(19) United States
(12) Patent Application Publication
(10) Pub. No.: US 2008/0268350 A1
(43) Pub. Date: Oct. 30, 2008

(54) SEMICONDUCTOR STRUCTURE

(75) Inventor: Chin-Cheng Yang, Hsinchu (TW)

Correspondence Address: J C PATENTS, INC., 4 VENTURE, SUITE 250, IRVINE, CA, 92618, US

(73) Assignee: MACRONIX INTERNATIONAL CO., LTD., Hsinchu (TW)

(21) Appl. No.: 11/742,408

(22) Filed: Apr. 30, 2007

(51) Int. Cl. G03F 1/14

(52) U.S. Cl. 430/5; 430/270.1

(57) ABSTRACT

A photomask is provided. The photomask includes a device pattern region, a die sealing pattern region and at least two alignment mark patterns. The device pattern region has a first side and a second side and the first side is opposite to the second side. The die sealing pattern region surrounds the device pattern region. The alignment mark patterns includes a first overlay mark pattern and a second overlay mark pattern and the first overlay mark pattern and the second overlay mark pattern are located outside the device pattern region and at the first side and second side respectively. An arrangement relationship between the first overlay mark pattern and the first side is a mirror of an arrangement relationship between the second overlay mark pattern and the second side.

### BACKGROUND OF THE INVENTION

1. Field of Invention

The present invention relates to a semiconductor structure. More particularly, the present invention relates to a photomask and an arrangement of the overlay marks.

2. Description of Related Art

In the manufacture of integrated circuit, photolithography process is used to transfer patterns from a photo mask having customized circuit patterns to thin films formed on a wafer. The image transfer process comprises steps of forming a photoresist layer on a non-process layer, illuminating the photoresist layer through a photo mask having the customized circuit patterns, developing the photoresist layer and then etching the non-process layer by using the patterned photoresist layer as a mask. Hence, the image transfer process is accomplished. For a well-manufactured integrated circuit product, the image transfer process mentioned above is performed several times to transfer the circuit patterns to each non-process layers to form the electrically circuit device. Therefore, it is important to align the successive patterned layers to reduce the misalignment errors as the critical dimension of the semiconductor device becomes smaller and smaller.

Typically, the overlay correlation parameters in an exposure tool are used to insure the alignment precision between the successive patterned layers. However, the overlay correlation parameters are seriously affected by the manufacturing variables. Specially, the study shows that the profiles of the sub-marks of the overlay mark are seriously affected by the film stress. That is, the sub-marks of the overlay mark are located in different positions with different stress level. Therefore, the sub-marks distort in different level and the mark center of the overlay mark shifts. Hence, even though the exposure tool is calibrated to accurately aligned the overlay marks of the successive material layer to the overlay marks of the previous material layer, the devices are misaligned in the shot region as the overlay marks in the previous material layer is already distorted.

### SUMMARY OF THE INVENTION

Accordingly, the present invention is to provide a photomask capable of improving overlay alignment accuracy.

The present invention is also to provide an arrangement of overlay alignment marks capable of eliminating the alignment deviation due to the distortion of the overlay alignment mark.

To achieve these and other advantages and in accordance with the purpose of the invention, as embodied and broadly described herein, the invention provides a photomask. The photomask comprises a device pattern region, a die sealing pattern region and at least two alignment mark patterns. The device pattern region has a first side and a second side and the first side is opposite to the second side. The die sealing pattern region surrounds the device pattern region. The alignment mark patterns comprises a first overlay mark pattern and a second overlay mark pattern and the first overlay mark pattern and the second overlay mark pattern are located outside the device pattern region and at the first side and second side respectively. An arrangement relationship between the first overlay mark pattern and the first side is a mirror of an arrangement relationship between the second overlay mark pattern and the second side.

According to one embodiment of the present invention, a first distance between the first overlay mark pattern and the first side is equal to a second distance between the second overlay mark pattern and the second side.

According to one embodiment of the present invention, the device pattern region is corresponding to a shot region on a wafer. Furthermore, the first overlay mark pattern is projected onto a first scribe line region aside the shot region on the wafer. Moreover, the second overlay mark pattern is projected onto a second scribe line region aside the shot region and opposite to the first scribe line region on the wafer.

The present invention also provides an overlay mark arrangement on a wafer. The wafer comprises several common scribe line regions, several die regions. The die regions are separated from each other by the common scribe line regions respectively. Each of the die regions is enclosed by a die sealing region. Each of the die regions comprises at least two overlay marks such as a first mark and a second mark located in a first common scribe line region and a second common scribe line region respectively. The first common scribe line region and the second common scribe line region are at the opposite sides of the die region. A first distance between the first mark and the die sealing is equal to a second distance between the second mark and the die sealing.

According to one embodiment of the present invention, the first mark is a mirror of the second mark.

According to one embodiment of the present invention, each die region is corresponding to a shot region in a photolithography process.

According to one embodiment of the present invention, the opposite sides of the die region comprise a first side corresponding to the first mark and a second side corresponding to the second mark. The arrangement relationship between the first mark and the first side is mirror of the arrangement relationship between the second mark and the second side.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a top view of a photomask according to one embodiment of the present invention.

FIG. 1A is a partial magnifying diagram showing one of the alignment mark pattern regions on the photomask shown in FIG. 1.

FIG. 1B is a partial magnifying diagram showing another alignment mark pattern region on the photomask shown in FIG. 1.

FIG. 2 is a top view of a wafer.

FIG. 3 is a partial magnifying diagram showing die regions on the wafer of FIG. 2 according to one embodiment of the present invention.

FIG. 3A is a partial magnifying diagram showing an alignment mark region 3A on the wafer shown in FIG. 2.

FIG. 3B is a partial magnifying diagram showing another alignment mark region 3B on the wafer shown in FIG. 2.

FIG. 3C is a partial magnifying diagram showing the other alignment mark region 3C on the wafer shown in FIG. 2.

FIG. 4 is a cross-sectional view of two overlay mark of a die region shown in FIG. 3.

### DESCRIPTION OF THE PREFERRED EMBODIMENTS

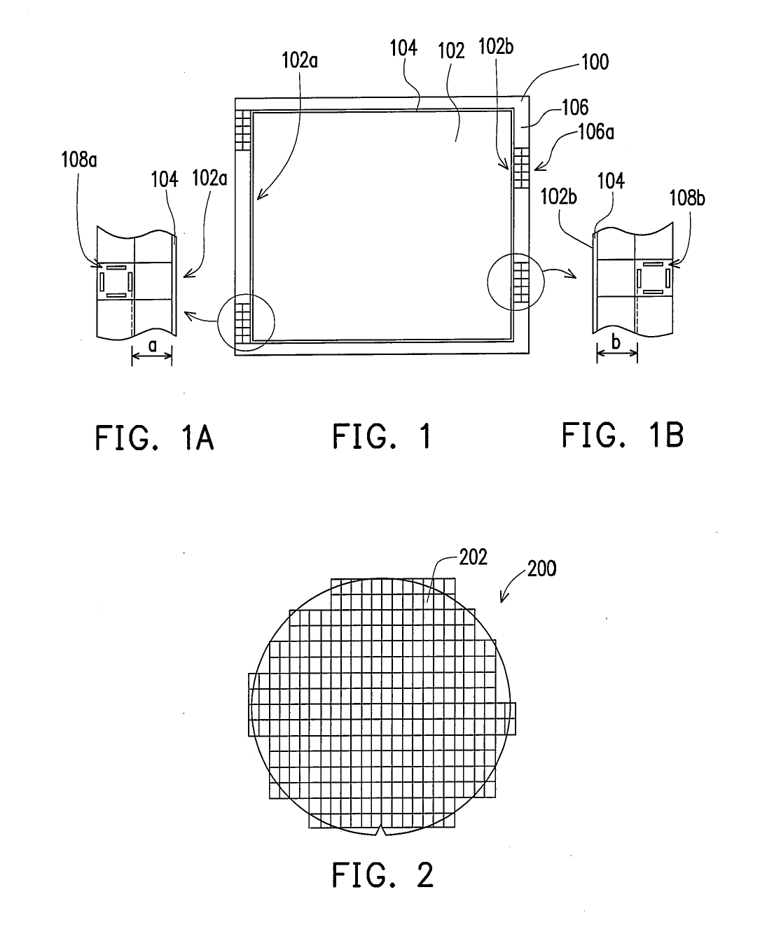

FIG. 1 is a top view of a photomask according to one embodiment of the present invention. As shown in FIG. 1, in the present invention, a photomask 100 having a device pattern region 102 is provided. The photomask 100 further comprises a die sealing pattern region 104 enclosing the device pattern region 102. Moreover, there is a spared region 106 on the photomask 100 and the spared region 106 surrounds both of the die sealing pattern region 104 and the device pattern region 102. Also, there are several alignment mark pattern regions 106a on the spared region 106 at opposite sides 102a and 102b of the device pattern region 102. FIG. 1A is a partial magnifying diagram showing one of the alignment mark pattern region on the photomask shown in FIG. 1 and FIG. 1B is a partial magnifying diagram showing another alignment mark pattern region on the photomask shown in FIG. 1. As shown in FIG. 1A and FIG. 1B, in the alignment mark pattern regions 106a on the opposite sides 102a and 102b of the device pattern region 102, a first overlay mark 108a outside the device pattern region 102 and aside the side 102a is a mirror of a second overlay mark 108b outside the device pattern region 102 and aside the side 102b. Furthermore, a distance a between the firs overlay mark 108a and a portion of the die sealing pattern region 104 aside the side 102a is equal to a distance b between the second overlay mark 108b and a portion of the die sealing pattern region 104 aside the side 102b. On the other words, the arrangement relationship between the first overlay mark 108a and a portion of the die sealing pattern region 104 aside the side 102a is a mirror of the arrangement relation ship between the second overlay mark 108b and a portion of the die sealing pattern region 104 aside the side 102b. That is, for the overlay marks located at opposite sides of the device pattern region 102, the arrangement of the overlay marks to the corresponding portions of the die sealing pattern region 104 are mirror of each other.

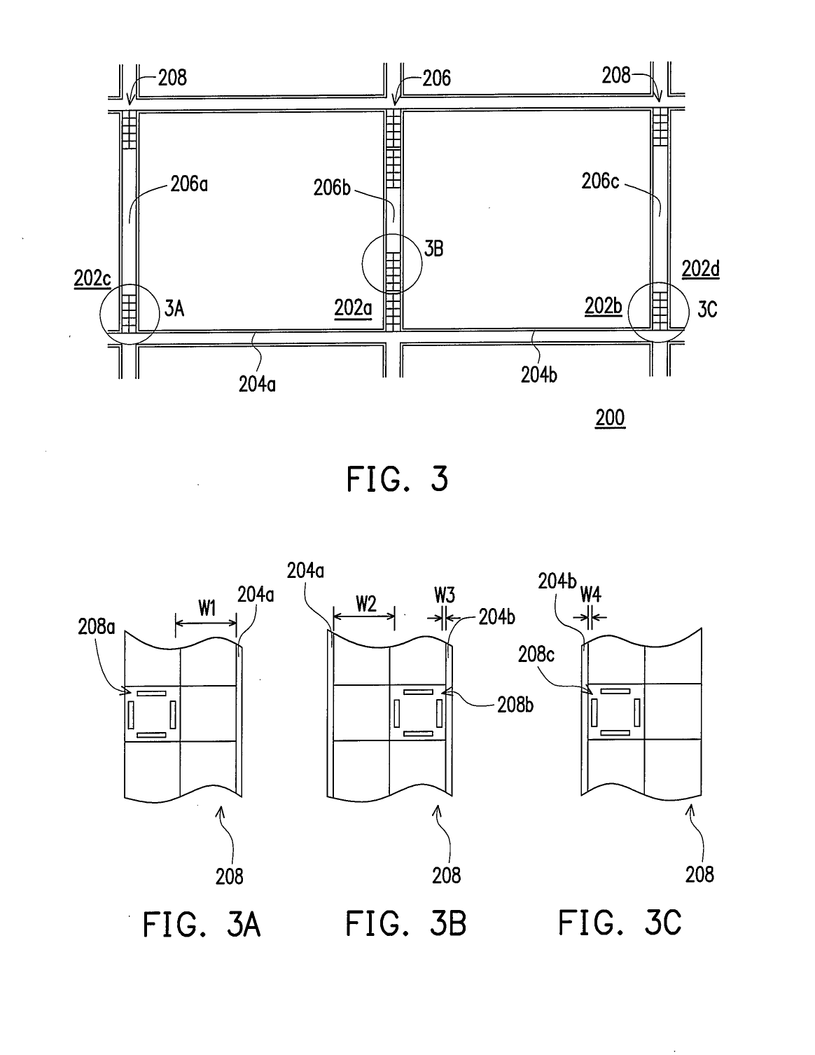

FIG. 2 is a top view of a wafer. By using the aforementioned photomask in a photolithography process, the device pattern region 102 shown in FIG. 1 is corresponding to a shot region or a die region 202 of a wafer 200. As shown in FIG. 2, the wafer 200 has several die regions 202. FIG. 3 is a partial magnifying diagram showing die regions on the wafer of FIG. 2 according to one embodiment of the present invention. As shown in FIG. 3, the die regions 202 are separated from each other by common scribe line regions 206. Taking the die regions 202a and 202b shown in FIG. 3 as an example, the die region 202a is separated from the die region 202b by a common scribe line region 206b. Also, the die region 202a is separated from the die region 202c by the common scribe line region 206a and the die region 202b is separated from the die region 202d by the common scribe lien region 206c. For each die region on the wafer 200, there is a die sealing region surrounding the die region and located between the die region and the common scribe line region. That is, the die region 202a is enclosed by a die sealing 204a and the die region 202b is enclosed by a die sealing 204b. Additionally, the common scribe line regions 206a and 206b are at the opposite sides of the die region 202a and the common scribe line regions 206b and 206c are at the opposite side of the die region 202b. Also, there are several alignment mark regions such as alignment mark regions 3A, 3B and 3C shown in FIG. 3 on the common scribe line regions respectively. During a shot of the photolithography process for copying the device pattern region 102 of the photomask 100 shown in FIG. 1 onto the die region 202a of the wafer 200, the first overlay mark 108a is projected onto the alignment mark region 3A in the common scribe line region 206a and the second overlay mark 108b is projected onto the alignment mark region 3B in the common scribe line region 206b.

FIG. 3A is a partial magnifying diagram showing an alignment mark region 3A on the wafer shown in FIG. 2. FIG. 3B is a partial magnifying diagram showing another alignment mark region 3B on the wafer shown in FIG. 2. FIG. 3C is a partial magnifying diagram showing the other alignment mark region 3C on the wafer shown in FIG. 2. As shown in FIG. 3, FIG. 3A and FIG. 3B, taking the die region 202a as an example, the alignment mark region 3A and the alignment mark region 3B are located at opposite side of die region 202a. Moreover, the distance w1 between a first overlay mark 208a and the die sealing 204a of the die region 202a is equal to the distance w2 between a second overlay mark 208b and the die sealing 204a of the die region 202a. Furthermore, the first overlay mark 208a is a mirror of the second overlay mark 208b. That is, the arrangement relationship between the first overlay mark 208a and a portion of the die sealing 204a aside the common scribe line region 206a is a mirror of the arrangement relationship between the second overlay mark 208b and a portion of the die sealing 204a aside the common scribe line region 206b. In addition, taking the die region 202b as an example, the alignment mark region 3B and the alignment mark region 3C are located at opposite side of die region 202b. Moreover, the distance w3 between the second overlay mark 208b and the die sealing 204b of the die region 202b is equal to the distance w4 between a third overlay mark 208c and the die sealing 204b of the die region 202b. Furthermore, the second overlay mark 208b is a mirror of the third overlay mark 208c. That is, the arrangement relationship between the second overlay mark 208b and a portion of the die sealing 204b aside the common scribe line region 206b is a mirror of the arrangement relationship between the third overlay mark 208c and a portion of the die sealing 204b aside the common scribe line region 206c. It should be noticed that the die region 202a and the die region 202b share a common scribe line region 206a and also share the second overlay mark 208b.

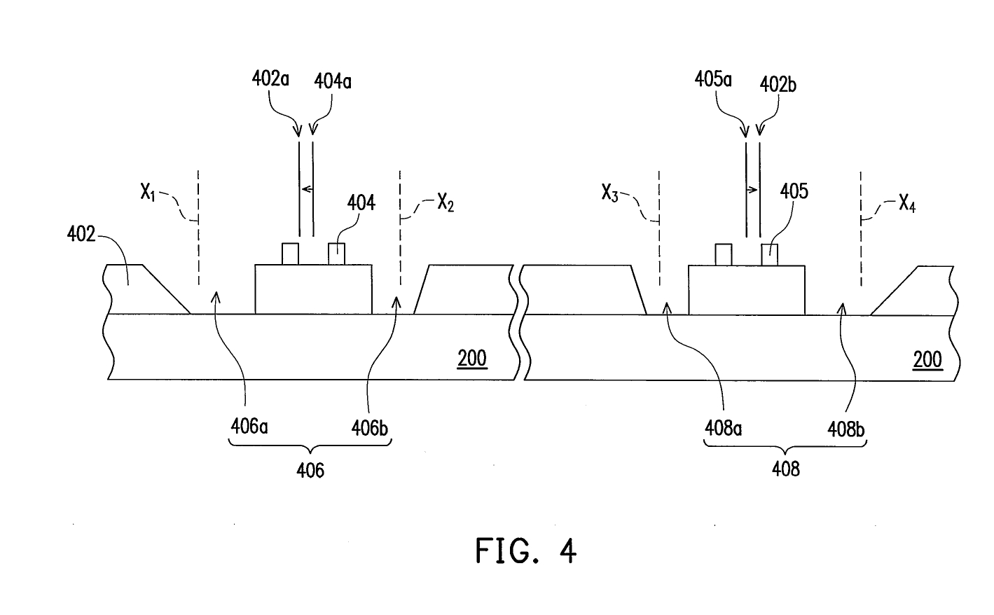

FIG. 4 is a cross-sectional view of two overlay mark of a die region shown in FIG. 3. As shown in FIG. 4, the overlay mark 406 is corresponding to the first overlay mark 208a shown in FIG. 3A and the overlay mark 408 is corresponding to the second overlay mark 208b shown in FIG. 3B. As for the overlay mark 406, since the sub-marks 406a and 406b of the overlay mark 406 is not located at the same arrangement environment, the profiles of the sub-marks 406a and 406b in the material layer 402 are affected by the stress in different level due to different arrangement environment so that the overly mark 406 is distorted. On the other words, because the overlay mark is not located at the center of the common scribe line region and the sub-marks are not arranged in the same position, the film stresses of the material layer for forming the sub-marks are different from each other. Therefore, it can be shown in FIG. 4, the profile distortion level of the sub-mark 406a is different from that of the sub-mark 406b. Hence, while another material layer with an overlay mark 404 is formed on the material layer 402, the mark center 404a of the overlay mark 404 cannot overlap with the mark center 402a of the overlay mark 406 since the mark center 402a of the overlay mark 406 has shifted. Similarly, the film stress at sub-mark 408a is different from that at sub-mark 408b of the overlay mark 408 because the sub-marks 408a and 408b are located at different position. Therefore, the overlay mark 408 is distorted and the mark center 405a of the later formed overlay mark 405 cannot overlap with the mark center 402b of the overlay mark 408. Because the arrangement relationship between the first overlay mark 208a and the portion of the die sealing 204a aside the common scribe line region 206a is the mirror of the arrangement relationship between the second overlay mark 208b and the portion of the die sealing 204a aside the common scribe line region 206b, the shift direction of the mark center 402a of the overlay mark 406 is opposite to the shift direction of the mark center 402b of the overlay mark 408. Also, the shifting amount of the mark center 402a of the overlay mark 406 is equal to the shifting amount of the mark center 402b of the overlay mark 408. Therefore, for the die region 202a, after the overlay correlation parameters are calculated by the exposure tool according to the measurement of the overlay marks in the material layer 402 and the successive material layer, the alignment deviation of the overlay mark in the common scribe line region 206a is compensated by the alignment deviation of the overlay mark in the common scribe line region 206b. Therefore, the alignment deviation due to the different film stress can be eliminated and the overlay correlation parameters do not been misled by the distortion of the overlay marks. Thus, the overlay alignment within the die region can be improved.

It will be apparent to those skilled in the art that various modifications and variations can be made to the structure of the present invention without departing from the scope or spirit of the invention. In view of the foregoing descriptions, it is intended that the present invention covers modifications and variations of this invention if they fall within the scope of the following claims and their equivalents.

What is claimed is:

1. A photomask comprising:
a device pattern region, wherein the device pattern region has a first side and a second side and the first side is opposite to the second side;
a die sealing pattern region surrounding the device pattern region; and
at least two alignment mark patterns comprising a first overlay mark pattern and a second overlay mark pattern, wherein the first overlay mark pattern and the second overlay mark pattern are located outside the device pattern region and at the first side and second side respectively, and an arrangement relationship between the first overlay mark pattern and the first side is a mirror of an arrangement relationship between the second overlay mark pattern and the second side.

2. The photomask of claim 1, wherein a first distance between the first overlay mark pattern and the first side is equal to a second distance between the second overlay mark pattern and the second side.

3. The photomask of claim 1, wherein the device pattern region is corresponding to a shot region on a wafer.

4. The photomask of claim 3, wherein the first overlay mark pattern is projected onto a first scribe line region aside the shot region on the wafer.

5. The photomask of claim 4, wherein the second overlay mark pattern is projected onto a second scribe line region aside the shot region and opposite to the first scribe line region on the wafer.

6. A wafer comprising:
a plurality of common scribe line regions;
a plurality of die regions, wherein the die regions are separated from each other by the common scribe line regions respectively, each of the die regions is enclosed by a die sealing region and each of the die regions comprises:
at least two overlay marks including a first mark and a second mark located in a first common scribe line region and a second common scribe line region respectively, wherein the first common scribe line region and the second common scribe line region are at the opposite sides of the die region and a first distance between the first mark and the die sealing is equal to a second distance between the second mark and the die sealing.

7. The wafer of claim 6, wherein the first mark is a mirror of the second mark.

8. The wafer of claim 6, wherein each die region is corresponding to a shot region in a photolithography process.

9. The wafer of claim 6, wherein the opposite sides of the die region comprise a first side corresponding to the first mark and a second side corresponding to the second mark and the arrangement relationship between the first mark and the first side is mirror of the arrangement relationship between the second mark and the second side.
